(19) United States
(12) Patent Application Publication
(10) Pub. No.: US 2026/0354243 A1
(43) Pub. Date: Nov. 5, 2026

(54) METHODS OF DIRECT COPPER BONDING

(71) Applicant: Applied Materials, Inc., Santa Clara, CA (US)

(72) Inventors: Poulomi MUKHERJEE, Santa Clara, CA (US); Robert MAY, Santa Clara, CA (US); Sarah WOZNY, Austin, TX (US); Loic CONSTANTIN, Santa Clara, CA (US)

(21) Appl. No.: 19/195,886

(22) Filed: May 1, 2025

(51) Int. Cl. H10W 72/00; H10W 72/90; H10W 80/00; H10W 99/00

(52) U.S. Cl. CPC H10W 72/019; H10W 72/90; H10W 99/00; H10W 72/01923; H10W 72/01931; H10W 72/01935; H10W 72/01951; H10W 72/921; H10W 72/923; H10W 72/934; H10W 72/952; H10W 72/953; H10W 80/312; H10W 80/327

(57) ABSTRACT

The present disclosure relates to a method of forming a package structure. The method includes depositing a bonding dielectric layer onto a surface of a base package structure. The bonding dielectric layer has a non-uniform thickness. The method also includes imprinting a pattern into the bonding dielectric layer to form one or more openings and forming a bonding conductor material in the one or more openings and above the bonding dielectric layer. A portion of the bonding conductor material is removed to expose at least a portion of the bonding dielectric layer.

### BACKGROUND

### Field

Embodiments of the present disclosure generally relate to electronic interconnects and methods of connecting electronic devices or package assemblies using electronic interconnects. More specifically, embodiments described herein relate to methods of connecting electronic devices using direct copper bonding.

### Description of the Related Art

Due to an ever-increasing demand for miniaturized electronic devices and components, the demand for faster processing capabilities with greater circuit densities imposes corresponding demands on the materials, structures, and processes used in the fabrication of such integrated circuit chips. Alongside these trends toward greater integration and performance, however, there exists the perpetual pursuit for reduced manufacturing costs.

In a copper direct bonding architecture, coplanarity of the metal and dielectric interfaces is important to achieving high resolution for small feature size. High thickness variation is a challenge for high density interconnects. A variation in thickness can lead to uneven bonding pressures and temperatures which impact the bond strength, and increase the risk of delamination which affects the device reliability.

There is a need, therefore, for improved methods of copper bonding to integrate electronic devices.

### SUMMARY

The present disclosure generally relates to copper electronic interconnects and methods of connecting electronic devices or package assemblies using copper electronic interconnects.

In one embodiment, a method of forming a package structure includes depositing a bonding dielectric layer onto a surface of a base package structure. The bonding dielectric layer has a non-uniform thickness. The method also includes imprinting a pattern into the bonding dielectric layer to form one or more openings and forming a bonding conductor material in the one or more openings and above the bonding dielectric layer. A portion of the bonding conductor material is removed to expose at least a portion of the bonding dielectric layer.

In another embodiment, a packaging method includes depositing a bonding dielectric layer having non-uniform thickness onto a patterned layer of a first package structure. The method also includes imprinting a pattern into the bonding dielectric layer to form one or more openings. Copper is deposited in the one or more openings and above the bonding dielectric layer. Then, a portion of the deposited copper is removed to expose at least a portion of the bonding dielectric layer. Thereafter, a second package structure is attached to the first package structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a flow diagram that illustrates a method of forming copper interconnects for connecting a package structure to another package structure, including an electronic device.

FIGS. 2, 3, 4, 5, 6, 7, and 8 illustrate the formation of one or more copper interconnects according to the method described in FIG. 1.

FIG. 9 illustrates a package structure connected to another package structure using direct copper bonding.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor advanced package assemblies and methods of forming the same. Specifically, the disclosure relates to a method of combining at least two built up package assemblies together. The method of combining two built up package assemblies together may include utilizing copper interconnects to connect the assemblies together. The combining process may include using copper direct bonding to bond layers of a first package structure to layers of a second package structure.

In some embodiments, the methods include depositing a bonding dielectric layer having non-uniform thickness onto an underlying patterned layer to compensate for the non-uniform height of the underlying patterned layer. The method also includes imprinting a pattern into the bonding dielectric layer to form one or more openings and forming a bonding conductor material in the one or more openings and above the bonding dielectric layer. A portion of the bonding conductor material is removed to expose at least a portion of the bonding dielectric layer.

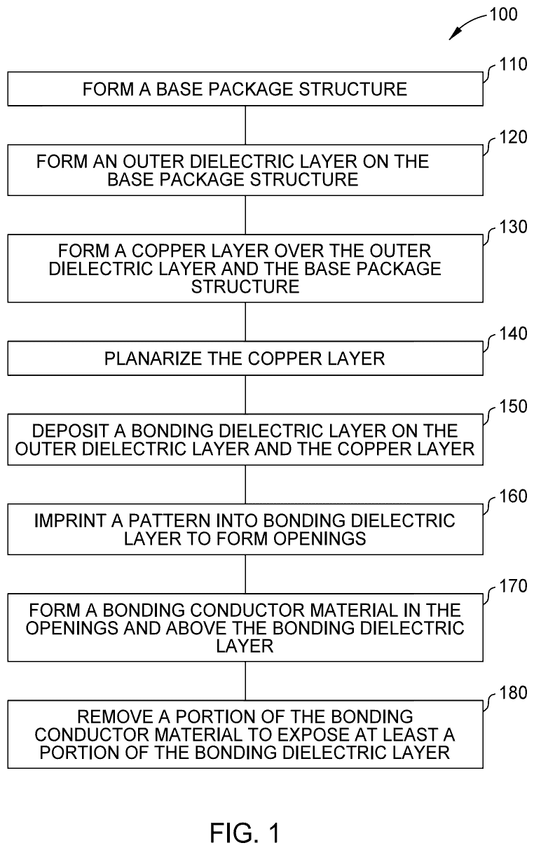

FIG. 1 is a flow diagram that illustrates a method of forming a package structure having a core structure that can be coupled to other package structures, including electronic devices. The core substrate may include organic cores or inorganic cores, such as silicon, glass, or silicon carbide.

The method begins with an operation 110 of forming a base package structure. The base package structure may be utilized for structural support and electrical interconnection layers formed thereon. In further examples, the base package structure may be utilized as a carrier structure for a surface-mounted device, such as a chip or graphics card. The base package structure may comprise a core structure, patterning layers, and through-assembly holes or vias (hereinafter referred to as “through-assembly vias”).

In one embodiment, the core structure includes a patterned (e.g., structured) substrate formed of any suitable substrate material. For example, the core structure includes a substrate formed from a III-V compound semiconductor material, silicon, crystalline silicon (e.g., Si<100>or Si<111>), silicon oxide, silicon germanium, doped or undoped silicon, doped or undoped polysilicon, silicon nitride, quartz, glass (e.g., borosilicate glass), sapphire, alumina, and/or ceramic materials. In one embodiment, the core structure includes a monocrystalline p-type or n-type silicon substrate. In one embodiment, the core structure includes a polycrystalline p-type or n-type silicon substrate. In another embodiment, the core structure includes a p-type or an n-type silicon solar substrate. In another embodiment the core structure may include a core substrate formed of a material that does not shrink much or does not shrink differentially during manufacturing processes, including heating of the core structure. The substrate utilized to form the core structure may further have a polygonal, rectangular, or circular shape. For example, the core structure may include a substantially square silicon, silicon carbide, or glass substrate having lateral dimensions between about 120 mm and about 550 mm, with or without chamfered edges. In another example, the core structure may include a circular silicon-containing wafer having a diameter between about 20 mm and about 700 mm, such as between about 100 mm and about 50 mm, for example about 300 mm. The core structure has a thickness T₁ between about 50 μm and about 1000 μm, such as a thickness T₁ between about 70 μm and about 800 μm.

The core structure may further include one or more holes or core vias (hereinafter referred to as “core vias”) formed therein to enable conductive electrical interconnections to be routed through the core structure. Generally, the one or more core vias are substantially cylindrical in shape. However, other suitable morphologies for the core vias are also contemplated. The core vias may be formed as singular and isolated core vias through the core structure or in one or more groupings or arrays.

Generally, the one or more core vias may be formed by laser ablation (e.g., direct laser patterning). Any suitable laser ablation system may be utilized to form the one or more core vias. In some examples, the laser ablation system utilizes an infrared (IR) laser source. In some examples, the laser source is a picosecond ultraviolet (UV) laser. The laser source is configured to form any desired pattern of features in the substrate, including the core vias.

The patterning layers may be formed on one or more surfaces of the core substrate. The patterning layers may be formed using a modified semi-additive process, a semi-additive process, a damascene process, or any suitable patterning method. Any suitable patterning method may include UV photolithography, etching, and direct laser patterning.

In one embodiment, the patterning layer is formed of polymer-based dielectric materials. For example, the patterning layer is formed from a flowable build-up material. In a further embodiment, the patterning layer is formed of an epoxy resin material having a ceramic filler, such as silica (SiO₂) particles. Other examples of ceramic fillers that may be utilized to form the patterning layer include aluminum nitride (AlN), aluminum oxide (Al₂O₃), silicon carbide (SiC), silicon nitride (Si₃N₄, Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. In some examples, the ceramic fillers utilized to form the patterning layer have particles ranging in size between about 40 nm and about 1.5 μm, such as between about 80 nm and about 1 μm.

One or more through-assembly vias may be formed through the patterning layer where the patterning layer extends into the core vias. For example, the through-assembly vias may be centrally formed within the core vias having the patterning layer disposed therein.

The through-assembly vias provide channels through which one or more electrical interconnections are formed in the base package structure. In one embodiment, the electrical interconnections are formed through the entire thickness of the base package structure (i.e., from a first major surface to a second major surface of the base package structure). In further embodiments, the electrical interconnections may protrude from a major surface of the base package structure, such as the major surfaces. The electrical interconnections may be formed of any conductive materials used in the field of integrated circuits, circuit boards, chip carriers, and the like. For example, the electrical interconnections may be formed of a metallic material, such as copper, aluminum, gold, nickel, silver, palladium, tin, or the like. As used herein, “copper” includes copper and alloys thereof.

In some embodiments, a final patterning layer is formed on a surface of the base package structure. The final patterning layer may be formed using any suitable patterning process including UV photolithography, etching, and direct laser patterning. The final patterning layer may be made of material similar to that of the patterning layers formed in the base package structure. In one example, the final patterning layer can include a resist material that is deposited over the surface of the base package structure.

Thereafter, copper is plated in the gaps between the features of the final patterning layer. The copper may be formed by use of an electroplating process that forms a copper layer over a copper seed layer, which is formed over surfaces of the gaps by any suitable deposition method including physical vapor deposition (PVD) and chemical vapor deposition (CVD).

After depositing the copper, the final patterning layer is removed from the surface of the base package structure by use of an ashing and/or etching process

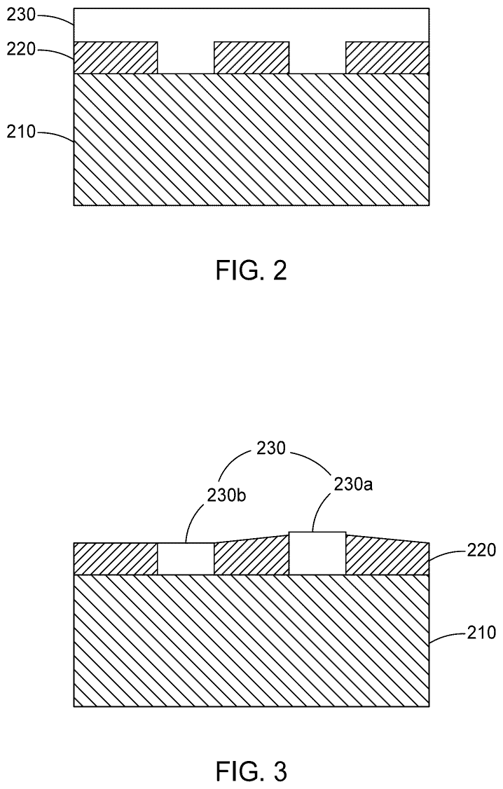

At operation 120, an outer dielectric layer 220 is formed on the top surface of the base package structure 210, as shown in FIG. 2. The outer dielectric layer 220 is formed in the gaps between the copper created by the removal of the final patterning layer, which was formed therebetween (not shown). The outer dielectric layer may also be formed in pads above the plated copper. The outer dielectric layer may be formed by any suitable patterning or deposition method. In one embodiment, the outer dielectric layer 220 may be formed of a dielectric material, such as a photoimageable polyimide or a non-photoimageable flowable buildup material such as a filled epoxy resin.

At operation 130, copper 230 is overplated on the top surface of the outer dielectric layer 220 and the package structure 210. The copper 230 may be formed by use of a copper electroplating process. The copper 230 overplating results in an amount of copper that extends above the top surface of the outer dielectric layer 220.

At operation 140, the copper 230 above the top surface of the outer dielectric layer 220 is removed via a planarization process. FIG. 3 shows the package structure 210 after the planarization process. The planarization process may include any suitable methods of planarizing such as a chemical mechanical polishing (CMP) process, mechanical grinding, fly-cutting or chemical etching. As seen in FIG. 3, the top surface of the package structure 210 may have some height variation. For example, FIG. 3 shows a first copper contact 230a that is taller than a second copper contact 230b. It can also be seen that portions of the outer dielectric layer 220 have different heights.

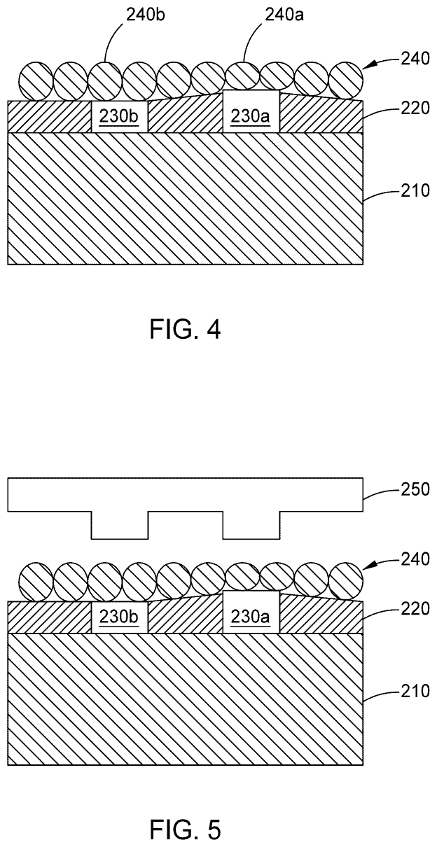

After the copper 230 is planarized, at operation 150, bonding dielectric features are formed above the outer dielectric layer 220 and above the planarized copper 230. In some embodiments, a bonding dielectric layer 240 formed on the outer dielectric layer 220 and the planarized copper 230. The bonding dielectric layer 240 can be formed by dispensing one or more bonding dielectric materials 240a, 240b in controlled volumes to correspond to the underlying pattern and to compensate for the height variation on the package structure 210, as shown in FIG. 4. For example, areas with electronic features that are taller (e.g., copper contact 230a) will receive a smaller volume of dielectric material (e.g., dielectric material 240a), and areas with electronic features that are shorter (e.g., copper contact 230b) will receive a larger volume of dielectric material (e.g., dielectric material 240b). In this respect, the volume of dielectric materials 240a, 240b can be deposited based on the underlying pattern to facilitate formation of a flat outer surface for bonding with another electronic device. In some embodiments, the dielectric materials 240a, 240b are printed onto the outer dielectric layer 220 and the planarized copper 230. In some embodiments, the dielectric materials 240a, 240b are printed using an inkjet printer. For example, the inkjet printer may deliver dielectric material droplets based on the pattern on the packaging structure 210. In some embodiments, the printed dielectric layer 240 has a height that is greater than the maximum height of the outer dielectric layer 220 and the planarized copper 230. As shown in FIG. 4, the bonding dielectric layer 240 formed by the bonding dielectric materials 240a, 240b has a non-uniform thickness. By controlling the volume of the dielectric droplets, embodiments of the present disclosure beneficially minimizes the potential for over-deposition or under-deposition in a given area on the packaging structure 210. In addition to the print process, the dielectric materials 240a, 240b can be deposited using a doctor blade process, a squeegee process, a spin coating process or any suitable deposition process capable of controlling the volume of the dielectric materials 240a, 240b to be deposited.

In one embodiment, the dielectric materials 240a, 240b are formed of polymer-based dielectric materials. For example, the dielectric materials are formed from a flowable build-up material or any polymer-based material suitable for imprinting. In some embodiments, the dielectric materials are a polyimide material. The dielectric materials 240a, 240b can be photosensitive or non-photosensitive. In a further embodiment, the dielectric materials are formed of an epoxy resin material having a ceramic filler, such as silica (SiO₂) particles.

At operation 160, an imprint process is performed to imprint a pattern into the dielectric layer 240 using a nano-imprint lithography (NIL) stamp, such as the NIL stamp 250 shown in FIG. 5. In some embodiments, the pattern can be imprinted using a thermal imprint process where the NIL stamp 250 is heated and the dielectric layer 240 comprises a non-photosensitive polyimide. In other embodiments, the imprint process is a UV NIL process where the dielectric layer 240 comprises a photosensitive polyimide.

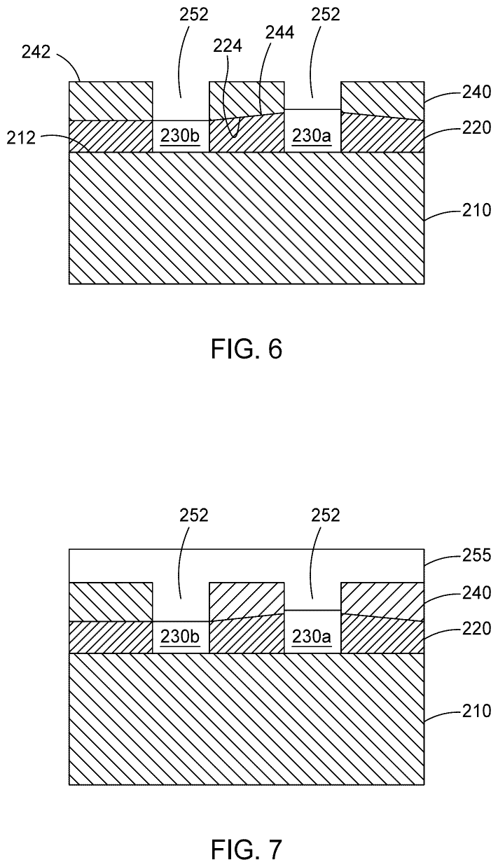

In this example, the NIL stamp 250 includes an interconnect pattern that corresponds to the underlying pattern of the outer dielectric layer 220 and the copper 230. In some embodiments, a single NIL stamp is used to form a plurality of openings in the dielectric layer 240 over the entire package structure 210 in a single imprint. The NIL stamp 250 may be heated to a temperature between about 200 °C and about 300 °C. The heated NIL stamp 250 is pressed into the dielectric material 240, which is displaced around the pattern of the NIL stamp 250. The NIL stamp 250 is subsequently cooled and removed from the dielectric layer 240 leaving one or more openings 252 formed therein, as shown in FIG. 6. After the imprint process, top surface 242 of the bonding dielectric layer 240 is flat or substantially flat. It can be seen that the dielectric layer 240 has a non-uniform thickness to compensate for the height variations of the outer dielectric layer 220. In addition, the bottom surface 244 of the bonding dielectric layer 240 is conformal to the top surface 224 of the outer dielectric layer 220. Further, the top surface 242 of the bonding dielectric layer 240 has coplanarity with the top surface 212 of the package structure 210. In one example, the distance between the top surfaces 212, 242 is no more than 10 nm, such as between 0.1 nm and 10 nm.

In some embodiments, the NIL stamp 250 is repeatedly pressed into the dielectric layer 240 until one or more openings 252 are formed in the dielectric layer 240 over all desired areas of the package structure 210. In some embodiments, the imprint process takes place in a low pressure atmosphere, such as in a processing system having a processing volume maintained at a pressure less than atmospheric pressure, such as less than one half of atmospheric pressure, or less than about 400 Torr, for example less than about 300 Torr. Physically imprinting a pattern into the dielectric layer 240 using a heated NIL stamp 250 in a low pressure atmosphere desirably removes, reduces, and/or substantially eliminates voids (not shown) formed in the dielectric layer 240 during and/or subsequent to the formation thereof.

After formation of the openings 252, the package structure 210 is optionally thermally cured in a nitrogen environment at a temperature between about 250 °C and 400 °C, such as between about 250 °C and 350 °C, or between about 325 °C and 400 °C, for example about 300 °C for a thermal NIL process.

At operation 170, the bonding conductor material is formed in the openings 252. In one embodiment, a seed layer (not shown) is deposited over the dielectric layer 240 and in the openings 252. In this example, the seed layer is a copper seed layer. In some examples, the seed layer comprises copper alloys with silver, gold, indium, ruthenium, cobalt, or combinations thereof. The seed layer is deposited using physical vapor deposition (PVD), or any suitable method such as atomic layer deposition (ALD), chemical vapor deposition (CVD), or combinations thereof.

After forming the seed layer, a layer of conductor material 255 is formed over the seed layer in the openings 252 and above the dielectric layer 240 using an electroplating process, as shown in FIG. 7. In this example, the bonding conductor material 255 is copper. In another embodiment, the conductor material 255 is deposited using direct printing of copper by depositing copper ink using an inkjet printer. Use of direct printing of the conductor material 255 may eliminate the need for additional CMP operation to remove excess conductor material 255. It is contemplated the layer of conductor material 255 may be formed using any suitable deposition process such as a doctor blade deposition process, a lamination process, PVD process or CVD process. The layer of conductor material 255 may be formed of any suitable bonding conductor material, such as copper alloys with silver, gold, nickel, indium, ruthenium, or cobalt. The deposition process results in an amount of the conductor material 255 disposed above the top surface of the dielectric layer 240.

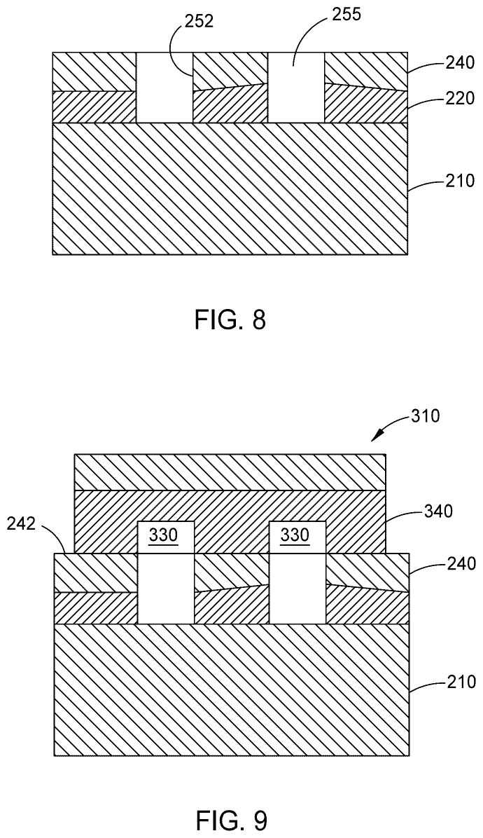

At operation 180, a planarization process is performed to remove the conductor material 255 (and the seed layer) disposed above the top surface of the dielectric layer 240 so that the conductor material 255 in the openings 252 has a top surface in line with the dielectric layer 240, as shown in FIG. 8. It is contemplated that one or more operations described herein may be optional, and the operations may be performed in any suitable order. For example, the method may begin at operation 150 and performed on a preformed patterned layer of a package structure.

In some embodiments, the package structure 210 may be bonded to another package structure 310, such as a die, using hybrid bonding as shown in FIG. 9. In one embodiment, the bonding dielectric layer 240 of the package structure 210 is bonded to the surface of a dielectric layer 340 of the package structure 310. In one example, the dielectric layer 240 is bonded to the dielectric layer 340 using fusion bonding.

In some embodiments, the package structure 210 is also bonded to the package structure 310 using copper direct bonding. In one example, the conductive material 230 of the package structure 210 is directly bonded to a copper interconnect 330 of the electronic device 310. The copper direct bonding may occur in several locations along the package structures 210, 310. The copper direct bonding may be formed using pressure and heat to form eutectic metal bonds. In the example of FIG. 9, the package structure 310 is disposed on the top surface of the 242 of the bonding dielectric layer 240 and is not embedded in the bonding dielectric layer 240.

After the package structures 210, 310 are bonded together via copper direct bonding, the resulting package assembly may be further bonded to other package assemblies. The direct copper bonding enables multiple layers and package assemblies of varying materials to be bonded together to create complex package assemblies comprising a multitude of materials and component types.

Embodiments of the disclosure beneficially use nano-imprint lithography for dielectric layer deposition to compensate for high thickness variation within the outer dielectric layer, which may facilitate conformality to the outer surface of the underlying layer of the package structure. The improved flatness of the bonding dielectric layer and coplanarity with the underlying package structure 210 enlarges the window available for copper direct bonding, such as more uniform bonding conditions like temperature and pressure, thereby improving the bond reliability. The ability to compensate for thickness variation will allow greater flexibility in design and integration for high density interconnect scenarios where surface topology vary significantly. Better conformality of the dielectric layer to the underlying uneven surface will also reduce the risk of voids and incomplete coverage, which may lead to better stress distribution and electrical isolation. Additionally, low thickness variation on the top surface of the dielectric layer may enable printing of the conductor material 230 as described above and thus, eliminate the need for additional CMP operation. Also, embodiments of the disclosure provide a package structure having improved electrical characteristics with reduced cross talk and interference, and effective heat dissipation by preventing hotspot creation.

While the foregoing is directed to embodiments of the present disclosure, other and further embodiments of the disclosure may be devised without departing from the basic scope thereof, and the scope thereof is determined by the claims that follow.

What is claimed is:

1. A method of forming a package structure, comprising:
depositing a bonding dielectric layer onto a surface of a base package structure, wherein the bonding dielectric layer has a non-uniform thickness;
imprinting a pattern into the bonding dielectric layer to form one or more openings;
forming a bonding conductor material in the one or more openings and above the bonding dielectric layer; and
removing a portion of the bonding conductor material to expose at least a portion of the bonding dielectric layer.

2. The method of claim 1, wherein depositing the bonding dielectric layer comprises depositing bonding dielectric material of at least two different sizes to form the bonding dielectric layer.

3. The method of claim 2, wherein depositing the bonding dielectric layer comprises printing the bonding dielectric material onto the surface of the base package structure.

4. The method of claim 2, wherein the bonding dielectric material comprises ink droplets of different sizes.

5. The method of claim 2, wherein the size of the bonding dielectric material is based on a height of the surface of the base package structure.

6. The method of claim 1, wherein the bonding dielectric layer comprises a polyimide.

7. The method of claim 1, wherein imprinting the pattern into the bonding dielectric layer comprises heating an imprint stamp to between about 200 °C and about 300 °C.

8. The method of claim 1, wherein the bonding conductor material comprises copper.

9. The method of claim 1, wherein forming the bonding conductor material comprises electroplating the bonding conductor material.

10. The method of claim 1, wherein forming the bonding conductor material comprises printing the bonding conductor material.

11. The method of claim 1, further comprising heating the bonding dielectric layer after imprinting.

12. The method of claim 1, wherein a top surface of the bonding dielectric layer has coplanarity with a top surface of the base package structure.

13. The method of claim 1, wherein the bonding dielectric layer is deposited onto an outer dielectric layer and a copper interconnect.

14. The method of claim 13, wherein the copper interconnect and the outer dielectric layer have different heights.

15. A packaging method, comprising:
depositing a bonding dielectric layer having non-uniform thickness onto a patterned layer of a first package structure;
imprinting a pattern into the bonding dielectric layer to form one or more openings;
depositing copper in the one or more openings and above the bonding dielectric layer;
removing a portion of the deposited copper to expose at least a portion of the bonding dielectric layer; and
attaching a second package structure to the first package structure.

16. The method of claim 15, wherein depositing the bonding dielectric layer comprises depositing bonding dielectric material of at least two different sizes to form the bonding dielectric layer.

17. The method of claim 16, wherein the bonding dielectric material comprises ink droplets of different sizes.

18. The method of claim 16, wherein the size of the bonding dielectric material is based on a height of the surface of the package structure.

19. The method of claim 15, wherein a top surface of the bonding dielectric layer has coplanarity with a top surface of the first package structure.

20. The method of claim 15, wherein the second package structure is attached to the first package structure using hybrid bonding.
